(19) United States
(12) Patent Application Publication
(10) Pub. No.: US 2016/0260492 A1
(43) Pub. Date: Sep. 8, 2016

(54) A READ VOLTAGE SETTING METHOD FOR A MEMORY SYSTEM INCLUDING MEMORY CELLS HAVING PLURALITY OF LOGIC STATES

(71) Applicant: SK hynix Inc., Gyeonggi-do (KR)

(72) Inventor: Byoung Sung YOU, Seoul (KR)

(21) Appl. No.: 14/835,347

(22) Filed: Aug. 25, 2015

(30) Foreign Application Priority Data
Mar. 6, 2015 (KR) 10-2015-0031734

(51) Int. Cl. G11C 16/26

(52) U.S. Cl. CPC G11C 16/26

(57) ABSTRACT

In a method of operating a memory system including memory cells having a plurality of voltage states, a plurality of page data are acquired from a selected page while sequentially applying, to a selected word line, a plurality of test voltages between a minimum voltage level and a maximum voltage level. Center voltages corresponding to at least some voltage states among the plurality of voltage states are detected based on the plurality of page data. Read voltages are set based on the detected center voltages. Data stored in the selected page is read by applying the to set read voltages to the selected word line.

### CROSS-REFERENCE TO RELATED APPLICATION

The present application claims priority to Korean patent application number 10-2015-0031734, filed on Mar. 6, 2015, the entire disclosure of which is herein incorporated by reference in its entirety.

### BACKGROUND

1. Field of Invention

The present invention relates to an electronic device and, more particularly, to a memory system and an operating method thereof.

2. Description of the Related Art

A semiconductor memory device is made of semiconductor materials such as silicon (Si), germanium (Ge), gallium arsenide (GaAs), or indium phosphide (InP), and the like. Semiconductor memory devices are generally classified into volatile and nonvolatile memory devices.

Volatile memory loses stored data when its power supply is cut off. Volatile memory includes static random access memory (SRAM), dynamic RAM (DRAM), synchronous DRAM (SDRAM), and the like. Nonvolatile memory retains stored data even without a constant source of power. Examples of nonvolatile memory include read only memory (ROM), programmable ROM (PROM), electrically programmable ROM (EPROM), electrically erasable and programmable ROM (EEPROM), flash memory, phase-change RAM (PRAM), Magnetoresistive RAM (MRAM), resistive RAM (RRAM), ferroelectric RAM (FRAM), and the like. Flash memory is generally classified into NOR flash memory and NAND flash memory.

### SUMMARY

Embodiments provide a memory system having improved reliability and an operating method thereof.

According to an aspect of the present invention, there is provided a method for operating a memory system including memory cells having a plurality of voltage states, the method including: acquiring a plurality of page data from a selected page while sequentially applying, to a selected word line, a plurality of test voltages between a minimum voltage level and a maximum voltage level; detecting center voltages corresponding to at least some voltage states, based on the plurality of page data; setting read voltages based on the detected center voltages; and reading data stored in the selected page by applying the set read voltages to the selected word line.

According to another aspect of the present invention, there is provided a memory system including: a semiconductor cell array including a plurality of pages respectively connected to a plurality of word lines, wherein each of the plurality of pages includes memory cells having a plurality of voltage states; and a controller suitable for acquiring a plurality of page data from a selected page by sequentially applying a plurality of test voltages between a minimum voltage level and a maximum voltage level, to a selected word line, and detecting center voltages corresponding to at least some voltage states among the plurality of voltage states, based on the plurality of page data, setting read voltages based on the detected center voltages, and reading data stored in the selected page by applying the set read voltages to the selected word line.

According to the present invention, it is possible to provide a memory system having improved reliability and an operating method thereof.

Example embodiments will now be described more fully hereinafter with reference to the accompanying drawings; however, the in invention may be embodied in different forms and should not be construed as limited to the embodiments set forth herein. Rather, these embodiments are provided so that this disclosure will be thorough and complete, and will fully convey the scope of the example embodiments to those skilled in the art.

In the drawings, dimensions may be exaggerated for clarity. It will be understood that when an element is referred to as being “between” two elements, it can be the only element between the two elements, or one or more intervening elements may also be present. Like reference numerals refer to like elements throughout.

### BRIEF DESCRIPTION OF THE DRAWINGS

FIG. 1 is a block diagram illustrating a memory system according to an embodiment of the present invention.

FIG. 2 is a block diagram illustrating a semiconductor memory device of FIG. 1.

FIG. 3 is a block diagram illustrating a memory cell array of FIG. 2.

FIG. 4 is diagram illustrating a threshold voltage distribution of memory cells when a least significant bit (LSB) program and a most significant bit (MSB) program are performed.

FIG. 5 is a diagram illustrating first to fourth voltage states are shifted after the MSB program is finished.

FIG. 6 is a flowchart illustrating an operating method of identifying data of a selected page by the memory system of FIG. 1.

FIG. 7 is a flowchart illustrating an embodiment of step S110 of FIG. 6.

FIG. 8 is a diagram Illustrating test voltages.

FIG. 9 is a diagram illustrating a method of detecting center voltages of changed second to fourth voltage states.

FIG. 10 is a diagram illustrating a method of setting read voltages in response to center voltages.

FIG. 11 is a conceptual diagram illustrating a look-up table.

FIG. 12 is a flowchart illustrating a method of operating a memory system according to an embodiment of the present invention.

FIG. 13 is a flowchart illustrating a method of operating a memory system according to another embodiment of the present invention.

FIG. 14 is a block diagram illustrating an embodiment for implementing the controller of FIG. 1.

FIG. 15 is a block diagram illustrating an applied example of the memory system of FIG. 1.

### DETAILED DESCRIPTION

In the following detailed description, only certain exemplary embodiments of the present invention have been shown and described. As those skilled in the art would realize, the described embodiments may be modified in various ways, all without departing from the spirit or scope of the present invention. Accordingly, the drawings and description are to be regarded as illustrative in nature and not restrictive.

In the entire specification, when an element is referred to as being “connected to” another element, it can be directly connected to or the another element or be indirectly connected to the another element with one or more intervening elements interposed therebetween. In addition, when an element is referred to as “including” a component, this indicates that the element may further include another component.

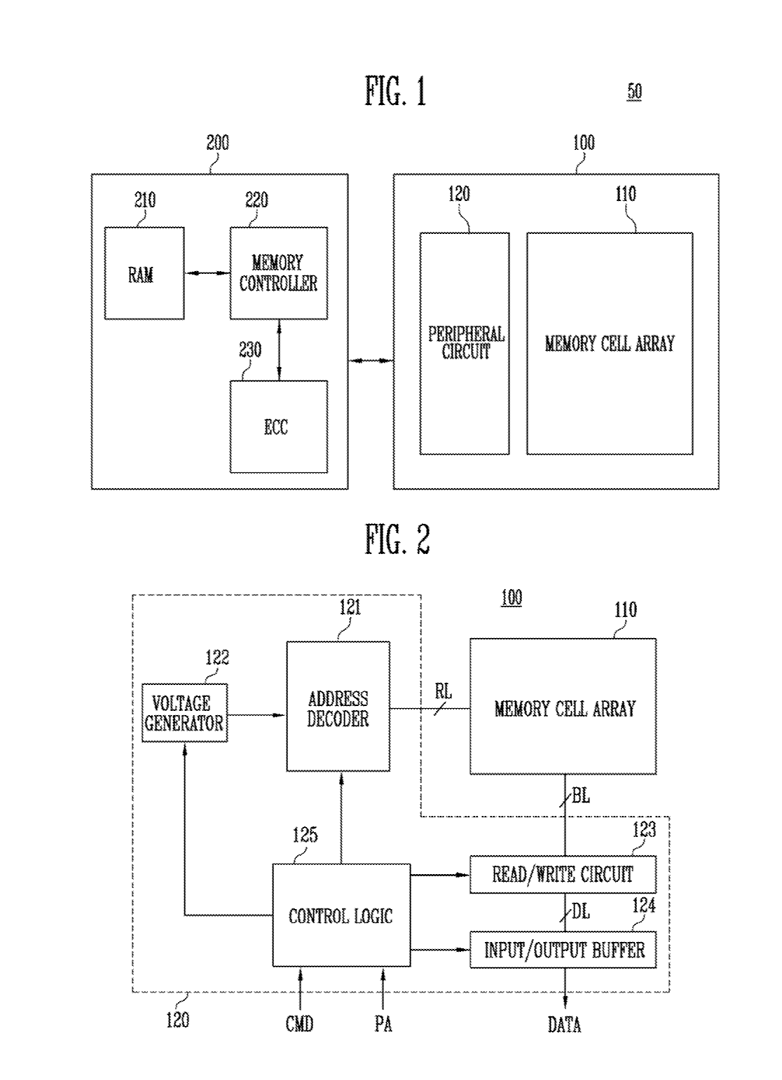

FIG. 1 is a block diagram illustrating a memory system 50 according to an embodiment of the present invention.

Referring to FIG. 1, the memory system 50 includes a semiconductor memory device 100 and a controller 200.

The semiconductor memory device 100 operates under the control of the controller 200. The semiconductor memory device 100 includes a memory cell array 110 and a peripheral circuit 120 for driving the memory cell array 110. The memory cell array 110 includes a plurality of nonvolatile memory cells.

The peripheral circuit 120 operates under the control of the controller 200. The peripheral circuit 120 programs data to the memory cell array 110 under the control of the controller 200. The peripheral circuit 120 is configured to read data from the memory cell array 110 and erase the data of the memory cell array 110.

In an embodiment, read and program operations of the semiconductor memory device 100 may be performed in units of pages. An erase operation of the semiconductor memory device 100 may be performed in units of memory blocks.

During the program operation, the peripheral circuit 120 may receive, from the controller 200, a command for performing the program operation, a physical block address, and write data, which indicate the program operation. One memory block and one page included therein may be selected by the physical block address. The peripheral circuit 120 may program the write data to the selected page.

During the read operation, the peripheral circuit 120 may receive, from the controller 200, a command for performing the read operation (hereinafter, referred to as a read command) and a physical block address, which indicates the read operation. One memory block and one page included therein may be selected by the physical block address. The peripheral circuit 120 may read data from the selected page, and output the read data (hereinafter, referred to as page data) to the controller 200.

During the erase operation, the peripheral circuit 120 may receive, from the controller 200, a command and a physical block address, which indicate the erase operation. The physical block address may specify one memory block. The peripheral circuit 120 may erase data of a memory block corresponding to the physical block address.

The semiconductor memory device 100 is a nonvolatile memory device. As an embodiment, the semiconductor memory device 100 may be a flash memory device.

The controller 200 controls general operations of the semiconductor memory device 100. The controller 200 is configured to access the semiconductor memory device 100 in response to a request from an external host.

The controller 200 includes a random access memory (RAM) 210, a memory controller 220, and an error correction block 230.

The RAM 210 operates under the control of the memory controller 220. The memory controller 220 is configured to control read, program, erase, and background operations of the semiconductor memory device 100. The memory controller 220 is configured to drive firmware for controlling the semiconductor memory device 100.

When the host transmits a read request, the memory controller 220 may provide a read command to the semiconductor memory device 100 to identify data of a page corresponding to the read request, i.e., a selected page. The memory controller 220 may convert a logical block address included in the read request into a physical block address. In an embodiment, the memory controller 220 serves as a flash translation layer FTL. The memory controller 220 may provide the converted physical block address together with the read command to the semiconductor memory device 100.

In response to the read command, the semiconductor memory device 100 reads page data from the selected page, and transmits the read page data to the controller 200. The error correction block 230 determines whether an error is included in the page data under the control of the controller 200. For example, the controller 200 may decode the page data based on an error correction code. Various error correction codes can be used. For example, error correction codes such as a Bose-Chaudhuri-Hocquenghem (BCH) code, a Reed-Solomon code, a Hamming code, and a low-density parity-check (LDPC) code, may be used as the error correction code. When the number of error bits included in the page data is greater than a predetermined number, the decoding of the page data may fail. When the number of the error bits included in the page data is less than or equal to the predetermined number, the decoding of the page data may succeed.

When the decoding of the page data succeeds, it may mean that the corresponding read command has passed. When the decoding of the page data fails, it may mean that the corresponding read command has failed. When the decoding of the page data succeeds, the controller 200 may output, to the host, the page data in which the error is corrected.

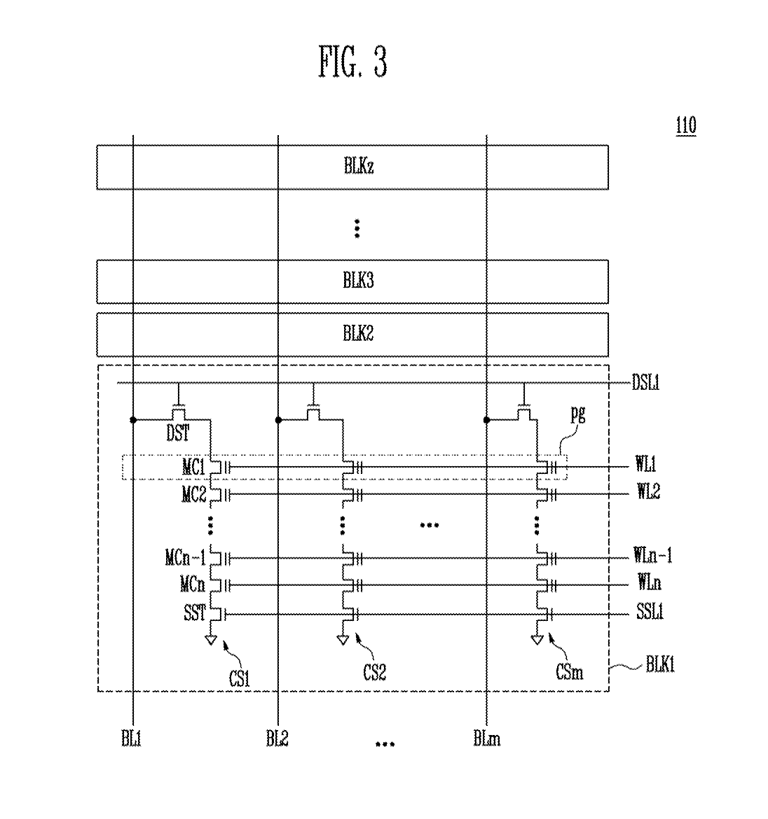

FIG. 2 is a block diagram illustrating the semiconductor memory device 100 of FIG. 1. FIG. 3 is a block diagram illustrating the memory cell array 110 of FIG. 2.

Referring to FIG. 2, the semiconductor memory device 100 includes the memory cell array 110 and the peripheral circuit 120.

The memory cell array 110 includes a plurality of memory cells. The plurality of memory cells are connected to an address decoder 121 through row lines RL and connected to a read/write circuit 123 through bit lines BL.

Referring to FIG. 3, the memory cell array 110 includes a plurality of memory blocks BLK1 to BLKz. The first to zth memory blocks BLK1 to BLKz are commonly connected to first to mth bit lines BL1 to BLm. The first to mth bit lines BL1 to BLm constitute the bit lines BL of FIG. 2. Each of the plurality of memory blocks BLK to BLKz constitutes an erase unit.

In FIG. 3, for convenience of illustration, elements included in one memory block BLK1 among the plurality of memory blocks BLK1 to BLKz are illustrated, and elements included in each of the other memory blocks BLK2 to BLKz are omitted. Each of the other memory blocks BLK2 to BLKz may be configured like the first memory block BLK1.

The memory block BLK1 includes a plurality of cell strings CS1 to CSm. The first to mth cell strings CS1 to CSm are connected to the first to mth bit lines BL1 to BLm, respectively.

Each of the plurality of cell strings CS1 to CSm includes a drain select transistor DST, a plurality of memory cells MC1 to MCn connected in series, and a source select transistor SST. The drain select transistor DST includes a gate connected to a drain select line DSL1. The first to nth memory cells MC1 to MCn include gates connected to first to nth word lines WL1 to WLn, respectively. The source select transistor SST includes a gate connected to a source select line SSL1.

A drain of the drain select transistor DST is connected to a corresponding bit line. A source of the source select transistor SST is connected to a reference voltage node. In an embodiment, the source of the source select transistor SST may be connected to a common source line (not shown), and the common source line may be biased with a reference voltage.

Memory cells connected to one word line among the first to mth cell strings CS1 to CSm constitute one page pg. Thus, the memory block BLK1 includes a plurality of pages.

The drain select line DSL1, the first to nth word lines WL1 to WLn, and the source select line SSL1 are included in the row lines RL of FIG. 2. The drain select line DSL1, the first to nth word lines WL1 to WLn, and the source select line SSL1 are controlled by the address decoder 121. The first to mth bit lines BL1 to BLm are controlled by the read/write circuit 123.

Referring back to FIG. 2, the peripheral circuit 120 includes the address decoder 121, a voltage generator 122, the read/write circuit 123 an input/output buffer 124, and a control logic 125.

The address decoder 121 is connected to the memory cell array 110 through the row lines RL. The address decoder 121 is configured to operate under the control of the control logic 125. The address decoder 121 receives a physical block address PA through the control logic 125.

The read operation of the semiconductor memory device 100 is performed in units of pages (see pg of FIG. 3). The physical block address PA received during the read operation includes a block address and a row address.

The address decoder 121 is configured to decode the block address included in the physical block address PA. The address decoder 121 selects one of memory blocks BLK1 to BLKz in response to the decoded block address.

The address decoder 121 is configured to select one word line in the memory block selected by decoding the row address included in the physical block address PA. Accordingly, one page is selected. The address decoder 121 may apply a read voltage (or test voltage) from the voltage generator 122 to the selected word line, and apply a pass voltage from the voltage generator 122 to unselected word lines.

The voltage generator 122 operates under the control of the control logic 125. The voltage generator 122 generates an internal power voltage by using an external power voltage supplied to the semiconductor memory device 100. For example, the voltage generator 122 may generate the internal power voltage by regulating the external power voltage. The internal power voltage generated as described above is provided to the address decoder 121, the read/write circuit 123, the input/output buffer 124, and the control logic 125 to be used as an operating voltage of the semiconductor memory device 100.

The voltage generator 122 generates a plurality of voltages by using at least one of the external power voltage and the internal power voltage. In an embodiment, the voltage generator 122 includes a plurality of pumping capacitors receiving the internal power voltage, and generates a plurality of voltages by selectively activating the plurality of pumping capacitors under the control of the control logic 125. For example, during the read operation, the voltage generator 122 may generate a read voltage and a pass voltage having a voltage level higher than that of the read voltage. The generated voltages may be applied to the address decoder 121.

The read/write circuit 123 is connected to the memory cell array 110 through the bit lines BL. The read/write circuit 123 operates under the control of the control logic 125.

During the read operation, the read/write circuit 123 reads and stores page data DATA from a selected page of the memory cell array 110. The page data DATA is transmitted to the input/output buffer 124 through data lines DL.

The input/output buffer 124 is connected to the read/write circuit 123 through the data lines DL. The input/output buffer 124 operates under the control of the control logic 125. The input/output buffer 124 outputs, to the controller 200 (see FIG. 1), the page data DATA transmitted from the read/write circuit 123 through the data lines DL.

The control logic 125 is configured to control the general operation of the semiconductor memory device 100. The control logic 125 may receive a command CMD and the physical block address PA. During the read operation, the command CMD may be a read command. During the program operation, the command CMD may be a command for performing the program operation. During the erase operation, the command CMD may be a command for performing the erase operation. The control logic 125 is configured to control the address decoder 121, the voltage generator 122, the read/write circuit 123, and the input/output buffer 124 in response to the received command CMD.

The control logic 125 may receive, as the command CMD, parameter setting information for changing setting values of the semiconductor memory device 100. The parameter setting information may include information for changing the read voltage. In this case, the control logic 125 may control the voltage generator 122 to adjust the read voltage based on the parameter setting information.

Threshold voltages of the memory cells included in each page may be shifted due to various factors. The read voltage applied to a selected word line is adjusted, thereby identifying data of the selected page as page data different from those of unselected pages. As an inappropriate read voltage is applied, many error bits may be included in the page data. However, the read voltage is adjusted, thereby reducing the error bits included in the page data. The memory controller 220 (see FIG. 1) may adjust the read voltage by providing parameter setting information as the command CMD to the semiconductor memory device 100, and then receive the page data of the selected page by transmitting a read command as the command CMD to the semiconductor memory device 100.

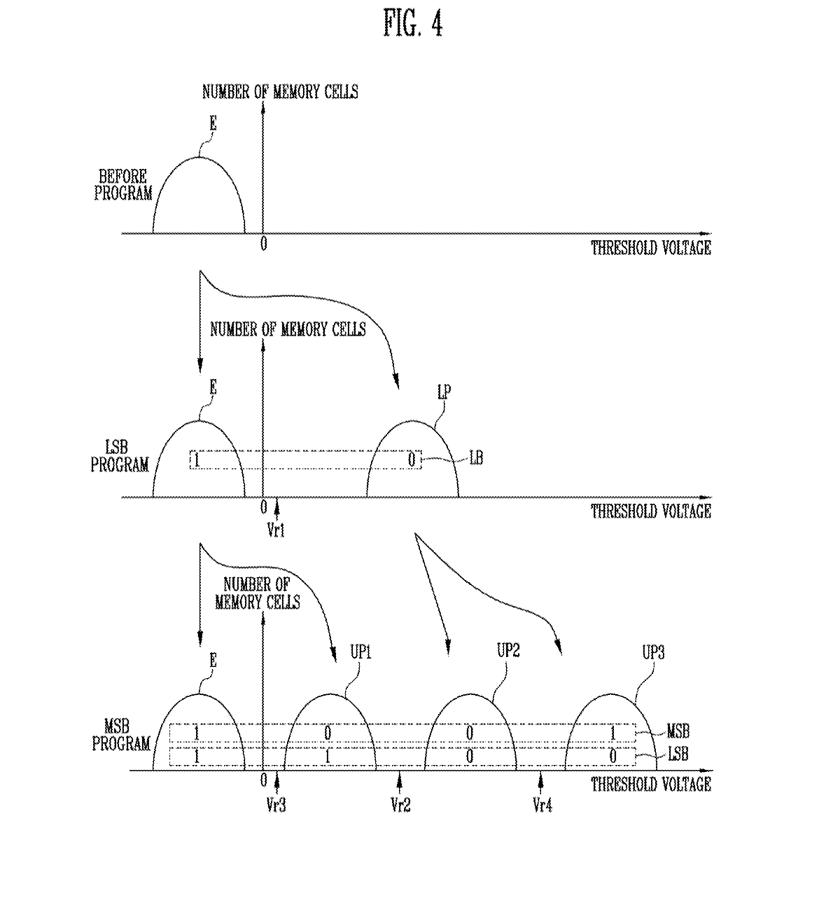

FIG. 4 is a diagram illustrating a threshold voltage distribution of memory cells when a least significant bit (LSB) program and a most significant bit (MSB) program are performed. In FIG. 4, the horizontal axis represents threshold voltages, and the vertical axis represents the number of memory cells.

Referring to FIG. 4, the memory cells have an erase state E before a program operation is performed. For example, a voltage range corresponding to the erase state E may be lover than the ground (0V). For example, it may be defined that the memory cells in the erase state E store a logic value of “1.”

As the LSB program is performed, the memory cells have two voltage states E and LP. The memory cells are programmed to have the erase state E or a lower program state LP. One data bit is stored in each memory cell, so that one LSB page is stored in a corresponding page pg (see FIG. 3). For example, it may be defined that the memory cell in the erase state E stores the logic value of “1,” and the memory cell in the lower program state LP stores a logic value of “0.”

When the LSB page is stored in the corresponding page and an MSB page is not stored in the corresponding page, a first read voltage Vr1 may be applied to the selected word line such that data of the LSB page is read as page data. The memory cell having a threshold voltage less than or equal to the first read voltage Vr1 may read as the logic value of “1.” The memory cell having a threshold voltage greater than the first read voltage Vr1 may be read as the logic value of “0.”

After the LSB program is performed, the MSB program is performed. As the MSB program is performed, the memory cells have four voltage states E, UP1, UP2, and UP3. According to program data, the memory cells in the erase state E and the lower program state LP are programmed to have the erase state E and first to third upper program states UP1 to UP3. For example, the memory cell in the erase state E may be programmed to have the erase state E or the first upper program state UP1, and the memory cell in the lower program state LP may be programmed to have the second upper program state UP2 or the third upper program state UP3.

Accordingly, two data bits are stored in each memory cell, so that the LSB page and the MSB page are stored in the corresponding page. The least significant bit LSB of each memory cell constitutes the LSB page. The most significant bit MSB of each memory cell constitutes the MSB page.

As an embodiment, the erase state E may correspond to a logic value of “11,” the first upper program state UP1 may correspond to a logic value of “01,” the second upper program state UP2 may correspond to a logic value of “00,” and the third upper program state UP3 may correspond to a logic value of “10.” That is, the least significant bits LSB of the erase state E and the first to third upper program states UP1 to UP3 may be defined as “1,” “1,” “0,” and “0,” respectively, and the most significant bits MSB of the erase state E and the first to third upper program states UP1 to UP3 may be defined as “1,” “0,” “0,” and “1,” respectively.

It is assumed that both the LSB and MSB pages are stored in the selected page. During a read operation on the LSB page, a second read voltage Vr2 may be applied to the selected word line such that data stored in the LSB page is read as page data. During a read operation on the MSB page, a third read voltage Vr3 may be applied to the selected word line such that a first read operation is performed, and a fourth read voltage Vr4 may be applied to the selected word line so that a second read operation is performed. Therefore, data stored in the MSB page may be identified based on a result of the first and second read operations.

As the number of data bits stored in each memory cell increases, the number of voltage states of the memory cells increases. As the number of voltage states increases, read margins between the voltage states may decrease. Therefore, it is required that the second to fourth read voltages Vr2 to Vr4 are positioned between read margins between the voltage states E, UP1, UP2, and UP3.

Hereinafter, for convenience of illustration, it is defined that the LSB and MSB pages are stored in the selected page, and the erase state E and the first to third upper program states UP1 to UP3 correspond to first to fourth voltage states, respectively.

FIG. 5 is a diagram illustrating that the first to fourth voltage states E, UP1, UP2, and UP3 are shifted after the MSB program is finished. In FIG. 5, the horizontal axis represents threshold voltages, and the vertical axis represents the number of memory cells.

Referring to FIG. 5, the second voltage state UP1 is shifted in the negative direction, and the corresponding memory cells have a changed second voltage state UP11. The third voltage state UP2 is shifted in the positive direction, and the corresponding memory cells have a changed third voltage state UP21. The fourth voltage state UP3 is shifted in the positive direction, and the corresponding memory cells have a changed fourth voltage state UP31.

In the semiconductor memory device 100, the memory cells are degraded as a program/erase cycle is repeated. For example, an oxide layer included In each memory cell is degraded and, therefore, electrons may be unintentionally trapped in the oxide layer. In this case, the threshold voltage of the corresponding memory cell may unintentionally increase. In FIG. 5, the changed third voltage state UP21 and the changed fourth voltage state UP31 correspond to this occurrence. The changed third voltage state UP21 has a voltage range higher than that of the third voltage state UP2. The changed fourth voltage state UP31 has a voltage range higher than the fourth voltage state UP3.

In the semiconductor memory device 100, the electrons trapped in the memory cell may leak after the program operation on the memory cell is finished. For example, the electrons trapped in a floating gate of the memory cell may leak as time elapses. In this case, the threshold voltage of the corresponding memory cell may unintentionally decrease. In FIG. 5, the changed second voltage state UP11 corresponds to this occurrence. The changed second voltage state UP11 has a voltage range lower than that of the second voltage state UP1. Particularly, when the voltage range of the changed second voltage state UP11 includes a negative voltage level, the read margin between the erase state E and the changed second voltage state UP11 further decreases.

In FIG. 5, it has been illustrated that the erase state E is not shifted. However, this is illustrative, and it will be understood that the erase state E may also be shifted in the positive or negative direction.

If the voltage ranges of the first to fourth voltage states E, UP1, UP2, and UP3 are changed, the second to fourth read voltages Vr2 to Vr4 may not be positioned between the read margins. If the read operation is performed in response to the second to fourth read voltages Vr2 to Vr4, the read page data may include many error bits.

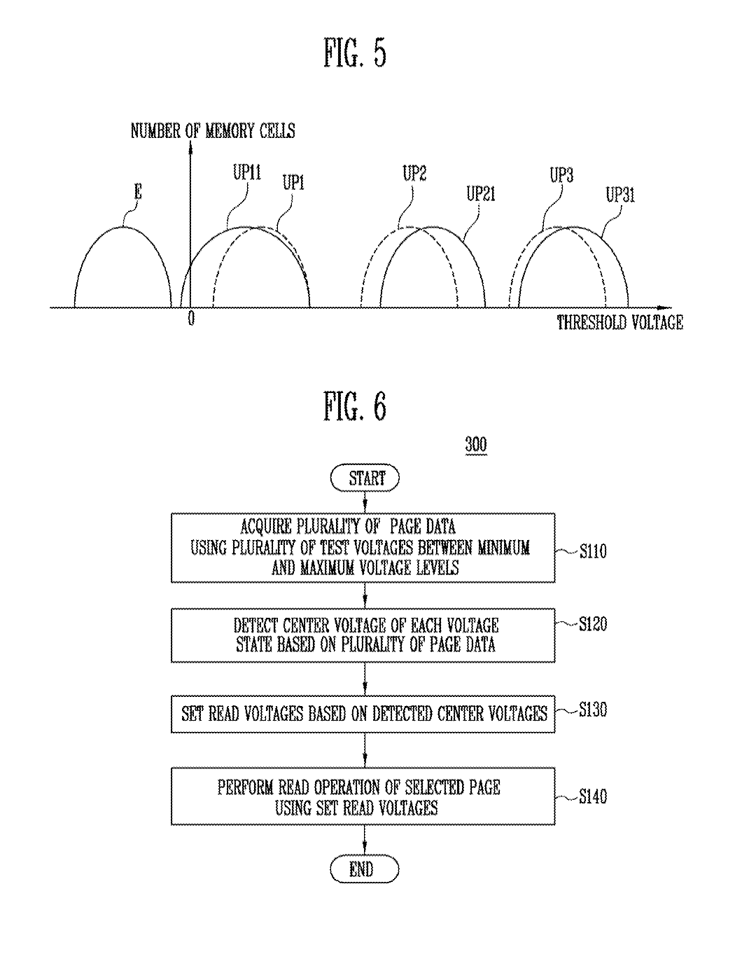

FIG. 6 is a flowchart illustrating an operating method 300 of identifying data of a selected page by the memory system 50 of FIG. 1. In FIG. 6, for convenience of illustration, it is assumed that LSB and MSB pages are stored in the selected page.

Referring to FIGS. 1 and 6, in step S110, the controller 200 acquires a plurality of page data from a page selected in response to a plurality of test voltages between minimum and maximum voltage levels. The minimum voltage level is a negative voltage level. The minimum and maximum voltage levels may be predetermined values. In an embodiment, the minimum voltage level may belong to the voltage range of the first voltage state E (see FIG. 5). The maximum voltage level is higher than the voltage ranges of the changed first to fourth voltage states E and UP11 to UP31 (see FIG. 5). Thus, the voltage range between the minimum and maximum voltage levels includes the voltage ranges of the second to fourth voltage states UP11, UP21, and UP31, except the first voltage state E.

Each test voltage may be applied to the selected word line such that the page data is acquired from the selected page. The acquired page data may be transmitted to the controller 200, and the memory controller 220 may store the transmitted page data in the RAM 210. ‘X’ page data may be acquired through ‘x’ read operations, where ‘x’ is a natural number. The second to fourth voltage states UP1, UP2, and UP3 may be determined based on the plurality of page data. A plurality of sampling data are generated based on the plurality of page data, thereby identifying a distribution of the second to fourth voltage states UP1, UP2 and UP3.

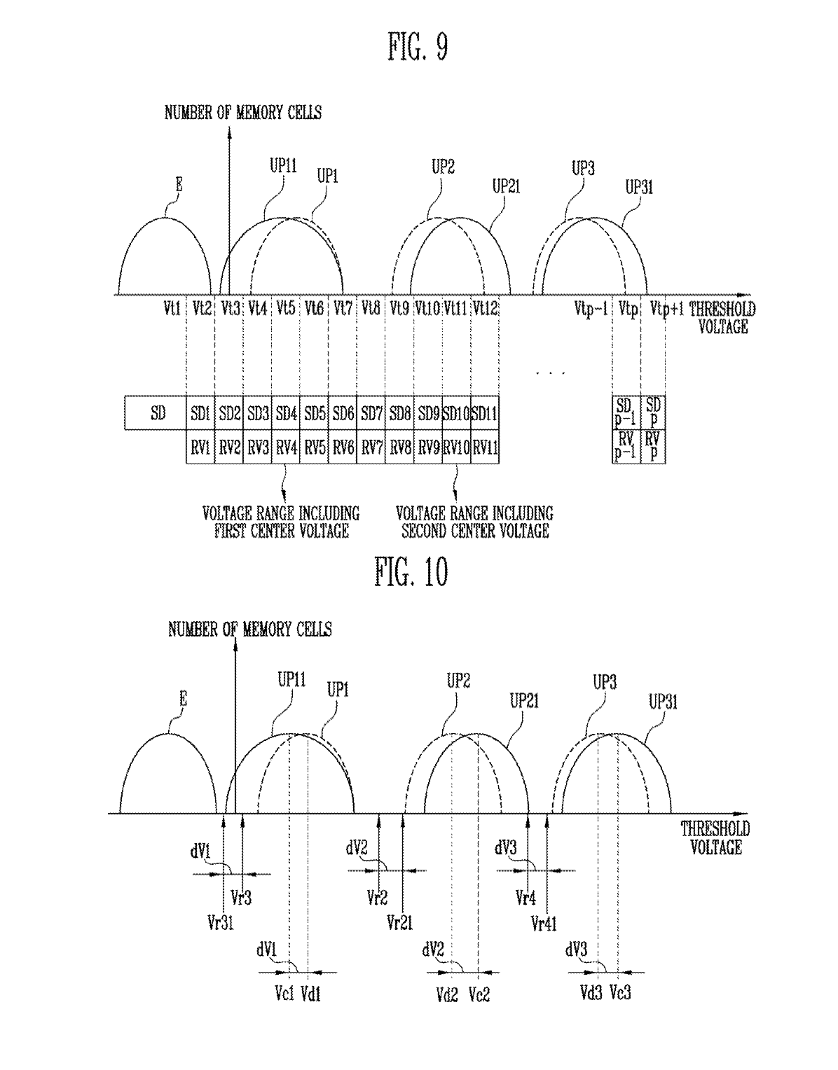

In step S120, the controller 200 detects a center voltage of each of the second to fourth voltage states UP1, UP2, and UP3 based on the plurality of page data. This will be described in detail with reference to FIG. 9.

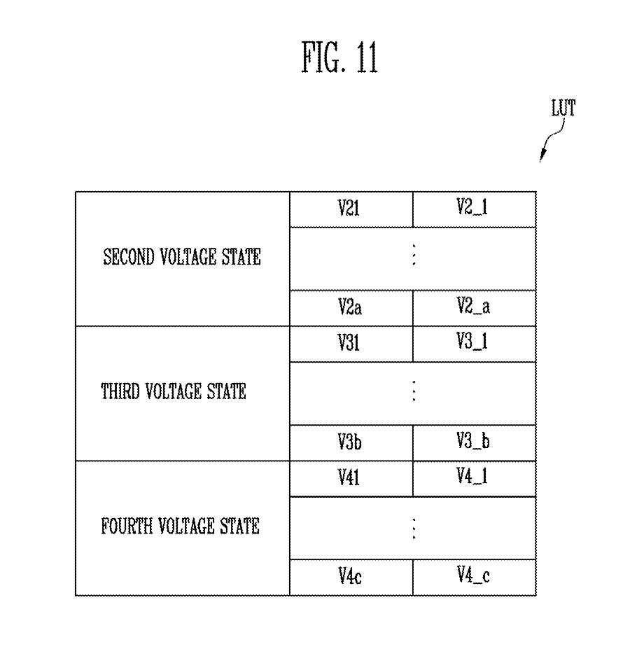

In step S130, the controller 200 sets read voltages corresponding to the second to fourth voltage states UP1, UP2, and UP3 based on the detected center voltages. This will be described in detail with reference to FIG. 10.

In step S140, the controller 200 performs a read operation on the selected page. Each read voltage set in step S130 may be applied to the selected word line such that the read operation on the selected page is performed. During the read operation on the MSB page, one of the set read voltages may be applied to the selected word line such that a first read operation is performed, and another of the set read voltages may be applied to the selected word line such a second read operation is performed. Therefore, data stored in the MSB page may be identified based on a result of the first and second read operations.

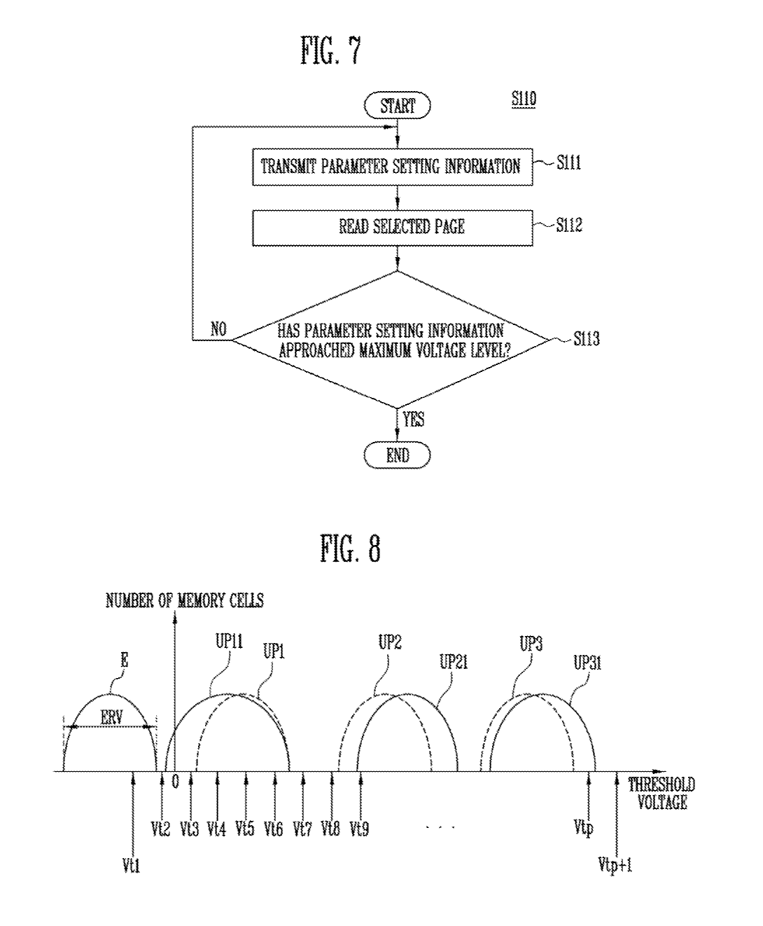

FIG. 7 is a flowchart illustrating an embodiment of step S110 of FIG. 6. FIG. 8 is a diagram illustrating test voltages Vt1 to Vtp+1. In FIG. 8, the horizontal axis represents threshold voltages, and the vertical axis represents the number of memory cells.

First, referring to FIGS. 1 and 7, in step S111, the memory controller 220 transmits parameter setting information to the semiconductor memory device 100. The parameter setting information includes information on the level of a test voltage to be generated in the voltage generator 122 (see FIG. 2). The control logic 125 sets the test voltage to be generated in the voltage generator 122 based on the parameter setting information.

In step S112, the memory controller 220 reads page data from the selected page of the semiconductor memory device 100. The memory controller 220 may transmit a read command and a physical block address indicating the selected page, to the semiconductor memory device 100. The semiconductor memory device 100 reads the page data from the selected page by applying the test voltage set in step S111 to the selected word line. The semiconductor memory device 100 transmits the read page data to the controller 200. The memory controller 220 stores the page data in the RAM 210.

In step S113, the memory controller 220 determines whether the parameter setting information has approached the maximum voltage level. Otherwise, steps S111 and S112 are repeatedly performed.

Referring to FIG. 8, the parameter setting information representing first to (p+1)th test voltages Vt1 to Vtp+1 may be sequentially transmitted whenever step S111 is performed. Whenever step S111 is performed, the level of the test voltage represented by the parameter setting information may increase. First to (p+1)th page data may be sequentially read in response to the first to (p+1)th test voltages Vt1 to Vtp+1.

As the difference between first to (p+1)th test voltages Vt1 to Vtp+1 decreases, the reliability of the center voltages detected in step S120 of FIG. 6 may increase. As the difference between first to (p+1)th test voltages Vt1 to Vtp+1 increases, the reliability of the center voltages detected in step S120 of FIG. 6 may decrease.

The first test voltage Vt1 may belong to the voltage range ERV of the first voltage state E. Accordingly, although the changed second voltage state UP11 adjacent to the first voltage state E is excessively shifted in the negative direction, the changed second voltage state UP11 may be more accurately identified.

FIG. 9 is a diagram illustrating a method of detecting center voltages of the changed second to fourth voltage states UP11 to UP31. In FIG. 9, the horizontal axis represents threshold voltages, and the vertical axis represents the number of memory cells.

Referring to FIG. 9, first to pth voltage ranges RV1 to RVp are defined by the first to (p+1)th test voltages Vt1 to Vtp+1. The memory controller 220 (see FIG. 1) calculates first to pth sampling data SD1 to SDp respectively corresponding to the first to pth voltage ranges RV1 to RVp, based on the plurality of page data.

As an embodiment, a q-th sampling data may be detected by comparing qth page data with (q+1)th page data, where q is a natural number that is greater than or equal to 1 and less than or equal to p. The qth page data and the (q+1)th page data may be compared for each data bit. A data bit of the qth page data may be compared with a corresponding data bit of the (q+1)th page data. The qth sampling data may represent the number of data bits which have a logic value of “0” in the qth page data and a logic value of “1” in the (q+1)th page data. Accordingly, each sampling data may represent the number of memory cells having threshold voltages belonging to a corresponding voltage range. Thus, the changed second to fourth voltage states UP11, UP21, and UP31 may be identified based on the first to pth sampling data SD1 to SDp.

When the value of the sampling data is great, it means that the center voltage belongs to the corresponding voltage range. In FIG. 9, it has been illustrated that the changed second voltage state UP11 belongs to the fourth voltage range RV4. The fourth sampling data SD4 may have a greater value than adjacent sampling data, e.g., SD2, SD3, SD5 and SD6. The memory controller 220 may detect that a first center voltage corresponding to the changed second voltage state UP11 belongs within the fourth voltage range RV4. The memory controller 220 may determine a voltage belonging to the fourth voltage range VR4 as the first center voltage. For example, the first center voltage may be determined as an average voltage in the fourth voltage range RV4. The tenth sampling data SD10 may have a greater value than adjacent sampling data, e.g., SD8, SD9, and SD11. The memory controller 220 may determine a voltage belonging to the tenth voltage range RV10 as a second center voltage corresponding to the changed third voltage state UP21. Although not shown in FIG. 1, the memory controller 220 may determine a voltage belonging to an r-th voltage range RVr as a third center voltage corresponding to the changed fourth voltage state UP31, where r is a natural number which is greater than or equal to 1 and less than and equal to p.

FIG. 10 is a diagram illustrating a method of setting read voltages in response to center voltages. In FIG. 10, the horizontal axis represents threshold voltages, and the vertical axis represents the number of memory cells.

Referring to FIG. 10, if first to third center voltages Vc1 to Vc3 are detected, the memory controller 220 compares first to third default voltages Vd1 to Vd3 with the respective first to third center voltages Vc1 to Vc3. The first to third default voltages Vd1 to Vd3 may be stored as meta information in a specific storage area within the memory cell array 110, and loaded in the RAM 210 after power-on. The first to third default voltages Vd1 to Vd3 correspond to the second to fourth voltage states UP1 to UP3, respectively. The memory controller 220 calculates a difference value between each center voltage and a corresponding default voltage. The memory controller 220 reflects the calculated difference value onto a corresponding read voltage.

In FIG. 10, the first center voltage Vc1 is lower by a first difference value dV1 than the first default voltage Vd1. This means that the changed second voltage state UP11 is shifted in the negative direction as compared with the second voltage state UP1. The corresponding third read voltage Vr3 is required to decrease. The memory controller 220 may select a read voltage Vr31 lower than the third read voltage Vr3 by the first difference value dV1.

The second center voltage Vc2 is higher than the second default voltage Vd2 by a second difference value dV2. This means that the changed third voltage state UP21 is shifted in the positive direction as compared with the third voltage state UP2. The corresponding second read voltage Vr2 is required to increase. The memory controller 220 may select a read voltage Vr21 higher than the second read voltage Vr2 by the second difference value dV2.

The third center voltage Vc3 is higher than the third default voltage Vd3 by a third difference value dV3. This means that the changed fourth voltage state UP31 is shifted in the positive direction as compared with the fourth voltage state UP3. The corresponding fourth read voltage Vr4 is required to increase. The memory controller 220 may select a read voltage Vr41 higher than the fourth read voltage Vr4 by the third difference value dV3.

It is assumed that the read operation on the LSB page performed. The memory controller 220 may control the semiconductor memory device 100 to use the read voltage Vr21 changed during the read operation by transmitting parameter setting information to the semiconductor memory device 100. Subsequently, during the read operation, the semiconductor memory device 100 may perform the read operation by applying the changed read voltage Vr21 to the selected word line. The semiconductor memory device 100 provides the read page data to the controller 200.

It is assumed that the read operation on the MSB page is performed. The memory controller 220 may control the semiconductor memory device 100 to use the read voltages Vr31 and Vr41 respectively changed during the first and second read operations by transmitting parameter setting information to the semiconductor memory device 100. Subsequently, the semiconductor memory device 100 may perform the first read operation by applying the changed read voltage Vr31 to the selected word line, and perform the second read operation by applying the changed read voltage Vr41 to the selected word line. The semiconductor memory device 100 identifies page data stored in the MSB page based on a result of the first and second read operations, and provides the identified page data to the controller 200.

According to an embodiment of the present invention, the controller 200 identifies center voltages of at least some voltage states, i.e., the changed second and third voltage states UP11 to UP31, among the voltage states E and UP11 to UP31 of the selected page, and controls read voltages in response to the identified center voltages. Accordingly, the read voltages may be efficiently determined within the read margins between the voltage states E and UP11 to UP31. Thus, the memory system 50 having improved reliability may be provided.

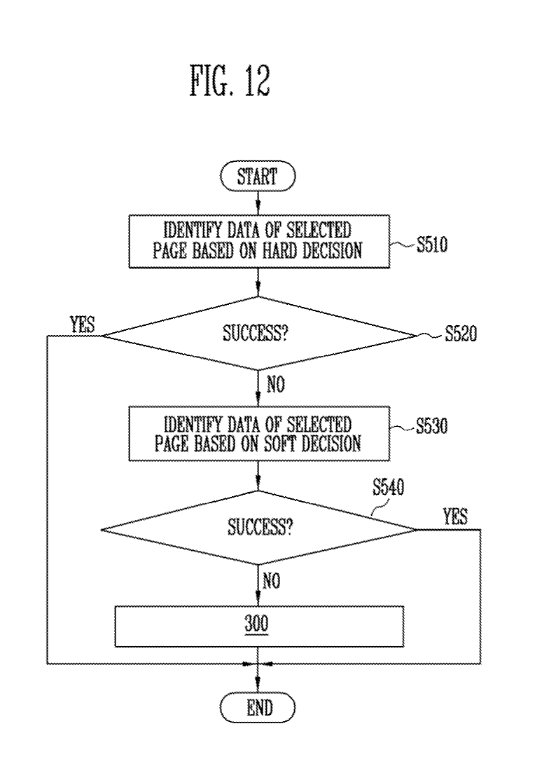

FIG. 11 is a conceptual diagram illustrating a look-up table LUT.

Referring to FIG. 11, the look-up table LUT stores a plurality of comparison voltages for each voltage state. First to a-th comparison voltages V21 to V2a corresponding to the second voltage state UP1 are defined in the look-up table LUT. First to b-th comparison voltages V31 to V3b corresponding to the third voltage state UP2 are defined in the look-up table LUT. First to c-th comparison voltages V41 to V4c corresponding to the fourth voltage state UP3 are defined in the look-up table LUT.

The look-up table LUT stores a voltage level corresponding to each comparison voltage. The first to a-th comparison voltages V21 to V2a of the second voltage state UP1 correspond to first to a-th voltage levels V2_1 to V2_a, respectively. The first to b-th comparison voltages V31 to V3b of the third voltage state UP2 correspond to first to b-th voltage levels V3_1 to V3_b, respectively. The first to c-th comparison voltages V41 to V4c of the fourth voltage level UP3 correspond to first to c-th voltage levels V4_1 to V4_c, respectively.

The look-up table LUT may be stored in the RAM 210. If a center voltage of each voltage state is determined, the memory controller 220 may search a comparison voltage corresponding to the determined center voltage in the look-up table LUT, and determine, as a read voltage, a voltage level corresponding to the searched comparison voltage. That is, if a center voltage of each voltage state is determined, the memory controller 220 may determine a read voltage by searching the determined center voltage in the look-up table LUT. The look-up table LUT is provided, so that a read voltage may be quickly acquired from the look-up table LUT without performing calculations for determining the read voltage after a center voltage is determined.

FIG. 12 is a flowchart illustrating a method of operating a memory system 50 according to an embodiment of the present invention.

Referring to FIGS. 1 and 12, in step S510, when a read request is received from the host, the controller 200 identifies data of a selected page based on a hard decision. The controller 200 may read page data of the selected page from the semiconductor memory device 100. The controller 200 may correct the page data based on an error correction code based on the hard decision. For example, the controller 200 may decode the page data based on the BCH code, the Reed-Solomon code, the Hamming code, or the like.

In step S520, when the error correction fails, step S530 is performed.

In step S530, the controller 200 identifies data of the selected page based on a soft decision. The controller 200 may read page data of the selected page from the semiconductor memory device 100. The controller 200 may correct the page data based on an error correction code based on the soft decision. For example, the controller 200 may decode the, page data based on the LDPC code, or the like.

In step S540, when the error correction based on the soft decision fails the operating method 300 which is illustrated in FIG. 6 may be performed.

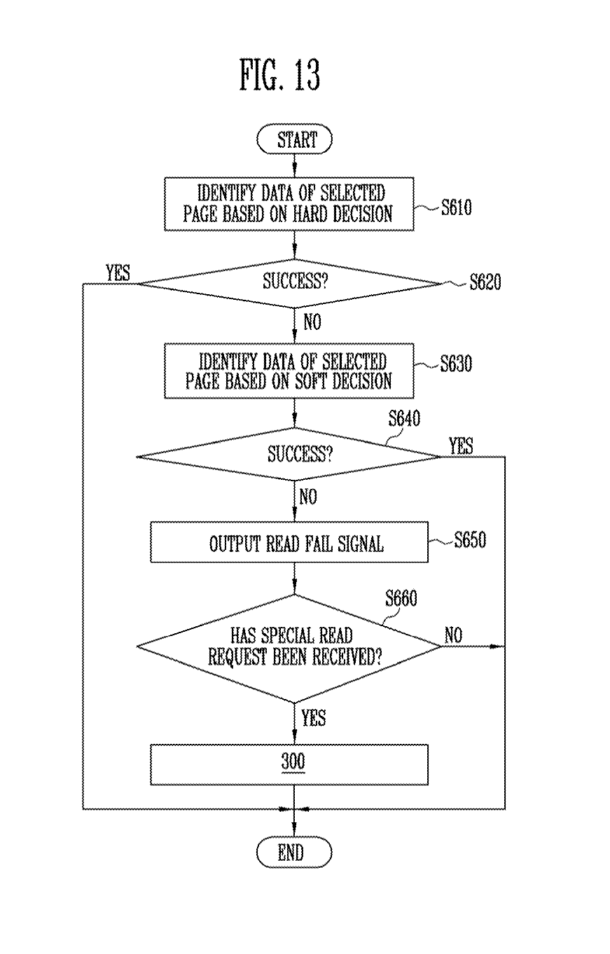

FIG. 13 is a flowchart illustrating a method of operating the memory system 50 according to another embodiment of the present invention.

Referring to FIGS. 1 and 13, steps S610 to S640 are described like steps S510 to S540 described with reference to FIG. 12. Hereinafter, overlapping descriptions will be omitted.

In step S650, when the error correction based on the soft decision fails, the controller 200 outputs a read fail signal to the external host. The external host may sense that the data of the selected page cannot be read in response to the read fail signal. In this case, the external host may additionally provide a special read request to the controller 200.

In step S660, the controller 200 determines whether the special read request has been received. If the special read request is received, the controller 200 may perform the operation method 300 described with reference to FIG. 6.

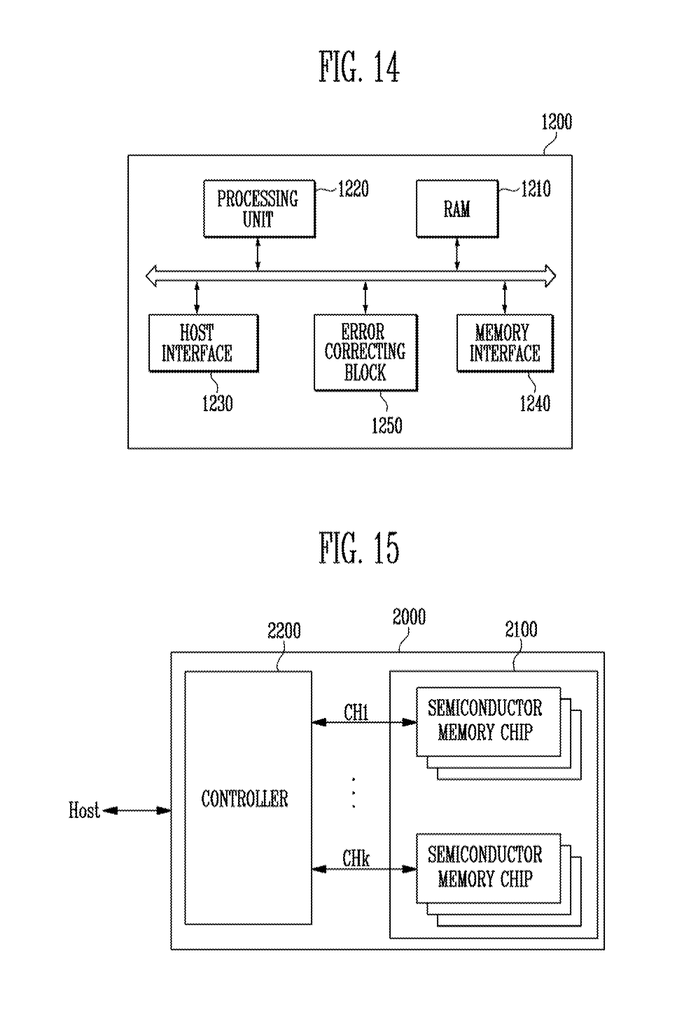

FIG. 14 is a block diagram illustrating an embodiment 1200 for implementing the controller 200 of FIG. 1.

Referring to FIG. 14, the controller 1200 includes a RAM 1210, a processing unit 1220, a host interface 1230, a memory interface 1240, and an error correcting block 1250.

The processing unit 1220 controls general operation of the controller 1200. The RAM 1210 may serve as at least one of an operation memory of the processing unit 1220, a cache memory between the semiconductor memory device 100 (see FIGS. 4 and 11) and the host, and a buffer memory between the semiconductor memory device 100 and the host. The processing unit 1220 and the RAM 1210 may perform the function of the memory controller 220 of FIG. 1. For example, the processing unit 1220 may load program commands, data files, data structures, and the like from the RAM 1210, and execute the loaded data, thereby performing the function of the memory controller 220.

Additionally, the RAM 1210 serves as the RAM 210 of FIG. 1. In FIG. 14, it has been illustrated that one RAM 1210 is provided. However, it will be understood that two or more RAMs may be provided.

The host interface 1230 includes a protocol for exchanging data between the host and the controller 1200. As an embodiment, the controller 1200 is configured to communicate with the host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, and a private protocol.

The memory interface 1240 interfaces with the semiconductor memory device 100. The error correcting block 1250 may decode page data based on an error correction code.

FIG. 15 is a block diagram illustrating an applied example 2000 of the memory system 50 of FIG. 1.

Referring to FIG. 15, the memory system 2000 includes a semiconductor memory device 2100 and a controller 2200. The semiconductor memory device 2100 includes a plurality of semiconductor memory chips. The plurality of semiconductor memory chips are divided into a plurality of groups.

In FIG. 15, it has been illustrated that the plurality of groups in the semiconductor memory devices communicate with the controller 2200 through first to k-th channels CH1 to CHk, respectively. Each semiconductor memory chip may be configured and operate like any one of the semiconductor memory devices 100 described with reference to FIG. 1.

Each group in the semiconductor memory devices is configured to communicate with the controller 2200 through one common channel. The controller 2200 is configured like the controller 1200 described with reference to FIG. 14. The controller 2200 is configured to control the plurality of memory chips of the semiconductor memory device 2100 through the plurality of channels CH1 to CHk.

In FIG. 15, it has been illustrated that a plurality of semiconductor memory chips are connected to one channel. However, it will be understood that the memory system 2000 may be modified such that one semiconductor memory chip is connected to one channel.

According to the embodiments of the present invention, the controller identifies center voltages of at least some voltage states of a selected page, and controls read voltages in response to the identified center voltages. Accordingly, read voltages may be efficiently determined within read margins between the voltage states. Thus, a memory system having improved reliability may be provided.

Embodiments have been disclosed herein, and although specific terms are employed, they are used and are to be interpreted in a generic and descriptive sense only and not for the purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and detail may be made without departing from the spirit and scope of the present invention as set forth in the following claims.

1. A method of operating a memory system including memory cells having a plurality of voltage states, the method comprising:
acquiring a plurality of page data from a selected page while sequentially applying, to a selected word line, a plurality of test voltages between a minimum voltage level and a maximum voltage level;
detecting center voltages corresponding to at least some voltage states, based on the plurality of page data;
setting read voltages based on the detected center voltages; and
reading data stored in the selected page by applying the set read voltages to the selected word line,
wherein the detecting of the center voltage includes:
with respect to the at least some voltage states, calculating sampling data corresponding to voltage ranges defined by the plurality of test voltages, based on the plurality of page data;
selecting, from the correspond voltage states, a voltage range having a greatest value of the sampling data; and
determining, as the center voltage, a voltage value which is in a selected voltage range.

2. The method of claim 1, wherein the minimum voltage level belongs within a voltage range of a lowest voltage state.

3. The method of claim 1, wherein the minimum voltage level includes a negative voltage level.

4. The method of claim 1, wherein the maximum voltage level is higher than voltage ranges of the voltage states.

5. The method of claim 1, wherein default voltages corresponding to the center voltages are defined, and
wherein the setting of the read voltages includes setting the read voltages based on a difference between each of the center voltages and a corresponding default voltage.

6. The method of claim 1, wherein the memory system stores a look-up table in which voltage levels corresponding to a plurality of comparison voltages are defined, and
wherein the setting of the read voltages includes searching comparison voltages corresponding to the detected center voltages among the comparison voltages in the look-up table, and setting voltage levels corresponding to the searched comparison voltages, to the read voltages.

7. (canceled)

8. The method of claim 1, wherein the sampling data corresponds to the number of memory cells corresponding to the voltage ranges.

9. The method of claim 1, further comprising:
identifying data of the selected page based on a hard decision.

10. The method of claim 9, further comprising:
identifying the data of the selected page based on a soft decision when the identification based on the hard decision fails.

11. The method of claim 10, wherein, when the identification based on the soft decision fails, the acquiring of the plurality of page data from the selected page while sequentially applying the plurality of test voltages to the selected word line is performed.

12. The method of claim 1, further comprising:
outputting of a read fail signal to a host when the identification based on the soft decision fails,
wherein, when a special read request is received from the host, the acquiring of the plurality of page data from the selected page while sequentially applying the plurality of test voltages to the selected word line is performed.

13. A memory system comprising:
a semiconductor cell array including a plurality of pages connected to a plurality of word lines, wherein each of the plurality of pages includes memory cells having a plurality of voltage states; and
a controller suitable for acquiring a plurality of page data from a selected page by sequentially applying a plurality of test voltages between a minimum voltage level and a maximum voltage level, to a selected word line, detecting center voltages corresponding to at least some voltage states among the plurality of voltage states, based on the plurality of page data, setting read voltages based on the detected center voltages, and reading data stored in the selected page by applying the set read voltages to the selected word line,
wherein the controller calculates sampling data corresponding to voltage ranges defined by the plurality of test voltages, based on the plurality of page data, and detects the center voltages in voltage ranges having greatest values of the sampling data in the corresponding voltage states.

14. The memory system of claim 13, wherein the minimum voltage level belongs within a voltage range of the lowest voltage state among the plurality of voltage states.

15. The memory system of claim 13, wherein the minimum voltage level includes a negative voltage level.

16. The memory system of claim 13, wherein the maximum voltage level is higher than voltage ranges of the plurality of voltage states.

17. The memory system of claim 13, wherein the controller stores default voltages corresponding to the center voltages, and sets the read voltages based on a difference between each of the center voltages and a corresponding default voltage.

18. The memory system of claim 13, wherein the controller stores a look-up table in which voltage levels corresponding to a plurality of comparison voltages are defined, searches comparison voltages corresponding to the detected center voltages among the comparison voltages in the look-up table, and sets voltage levels corresponding to the searched comparison voltages, to the read voltages.

19. (canceled)

20. The memory system of claim 13, wherein the sampling data corresponds to the number of memory cells corresponding to the voltage ranges.
